(19) United States
(12) Patent Application Publication
(10) Pub. No.: US 2014/0362550 A1
(43) Pub. Date: Dec. 11, 2014

(54) SELECTIVE WETTING PROCESS TO INCREASE SOLDER JOINT STANDOFF

(71) Applicant: NVIDIA CORPORATION, Santa Clara, CA (US)

(72) Inventor: Leilei ZHANG, Sunnyvale, CA (US)

(21) Appl. No.: 13/915,205

(22) Filed: Jun. 11, 2013

(51) Int. Cl. H05K 1/11; H01L 23/00

(52) U.S. Cl. CPC H05K 1/111; H01L 24/81
USPC 361/767; 438/107; 174/261; 174/257

(57) ABSTRACT

One embodiment of the invention sets forth a packaging system, which includes a first package substrate, an electrically conductive pad formed on a surface of the first package substrate, and a supporting structure formed on the electrically conductive pad. The supporting structure has a top surface and a side surface, and only the top surface of the supporting structure is coupled to a solder joint to establish an electrical connection between the first package substrate and an adjacent, parallel second package substrate. By having the solder joint connected only to the top surface of the supporting structure, the resulting solder joint structure is narrower and taller. Therefore, even if solder joints are placed at a finer pitch, a standoff height between the first and second package substrates can be maintained at a desired height to accommodate a fixed-size IC chip that is disposed between the first and second package substrates.

### BACKGROUND OF THE INVENTION

1. Field of the Invention

Embodiments of the present invention generally relate to integrated circuit chip packaging and, more specifically, to a selective wetting process to increase solder joint standoff height in a package-on-package (POP) packaging system.

2. Description of the Related Art

With the development of the electronics industry, there are increasing demands for smaller electronic devices with improved performance. In order to achieve a higher integration density and a smaller footprint for electronic components, a so-called “package-on-package (PoP)” technology has been developed. PoP is a three-dimensional packaging technology used to vertically stack multiple semiconductor packages on top of each other with interfaces to route signals between them.

Flip-chip bonding technique is one of the assembly approaches used in the PoP packaging to provide the integrated circuit package system with greater integration density. Flip-chip bonding utilizes one or more solder bumps formed on a respective bond pad to establish electrical contact between a package substrate and another chip package. FIG. 1 illustrates a schematic sectional view of a conventional PoP packaging system 100 using non solder mask defined (NSMD) bond pads 102. As shown, a package substrate 104 is electrically connected to a low-power chip 106 (e.g., a memory device) by solder bumps 108. Each solder bump 108 electrically connects to respective bond pad 102 formed on the package substrate 104, which is in electrical communication with a printed circuit board (not shown) through solder balls 118. For NSMD bond pads 102, the bond pad 102 is smaller than a solder mask opening 114 that is defined by a solder mask layer 112 formed on the surface of the package substrate 104. Conductive lines 116 and 124, which connect to bond pads and solder bumps 122 respectively, may run through the package substrate 104 to provide signals and/or power from the PCB to the low-power chip 106 and a high-power chip 120 (e.g., a processor) that is disposed between the package substrate 104 and the low-power chip 106.

As device sizes decrease, the pitch “P,” i.e., the center-to-center distance between the solder bumps 108, has to be reduced so that the connections between the low-power chip 106 and the package substrate 104 can be created and maintained within a smaller space. However, the standoff height (i.e., the distance “H” between the low-power chip 106 and the package substrate 104), unlike the pitch “P”, has not been reduced because the height of the high-power chip 120 has not changed. As FIG. 1 clearly illustrates, the distance “H” must be substantially maintained in order for the high-power chip 120 to fit properly in between the low-power chip 106 and the package substrate 104. Consequently, a design problem arises —if the pitch is reduced, the solder bumps 108 cannot necessarily maintain their width; however, the height of the solder bumps 108 needs to be substantially maintained. In short, the aspect ratio of the conventional solder bumps needs to effectively change.

As the foregoing illustrates, what is needed in the art is a soldering approach that allows the standoff distance “H” to be substantially maintained in PoP designs that mandate reduced distances or pitches between solder bumps.

### SUMMARY OF THE INVENTION

One embodiment of the present invention sets forth a packaging system. The packaging system includes a first package substrate, an electrically conductive pad formed on a surface of the first package substrate, a supporting structure formed on the electrically conductive pad, where the supporting structure includes a top surface and a side surface, and a solder joint coupled to the top surface and not to the side surface.

One advantage of the disclosed embodiments is that the solder joint standoff can be maintained at a desired height to accommodate the fixed-size high-power chip mounted on the package substrate, even with the closer spacing resulting from fine-pitch solder bumps. Therefore, for the particular width of solder bump, the solder joint standoff can be increased, as compared to the conventional approach where the solder bump covers all exposed surfaces of the post structure.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an integrated circuit (IC) system, according to one embodiment of the invention.

FIG. 2 illustrates an exemplary process sequence used to form an integrated circuit system, according to one embodiment of the invention.

FIGS. 3A-3G illustrate schematic cross-sectional views of an integrated circuit (IC) system 300 at different stages of the process sequence shown in FIG. 2.

FIG. 4 illustrates a partial, schematic cross-sectional view of an integrated circuit (IC) system, according to one embodiment of the invention.

### DETAILED DESCRIPTION

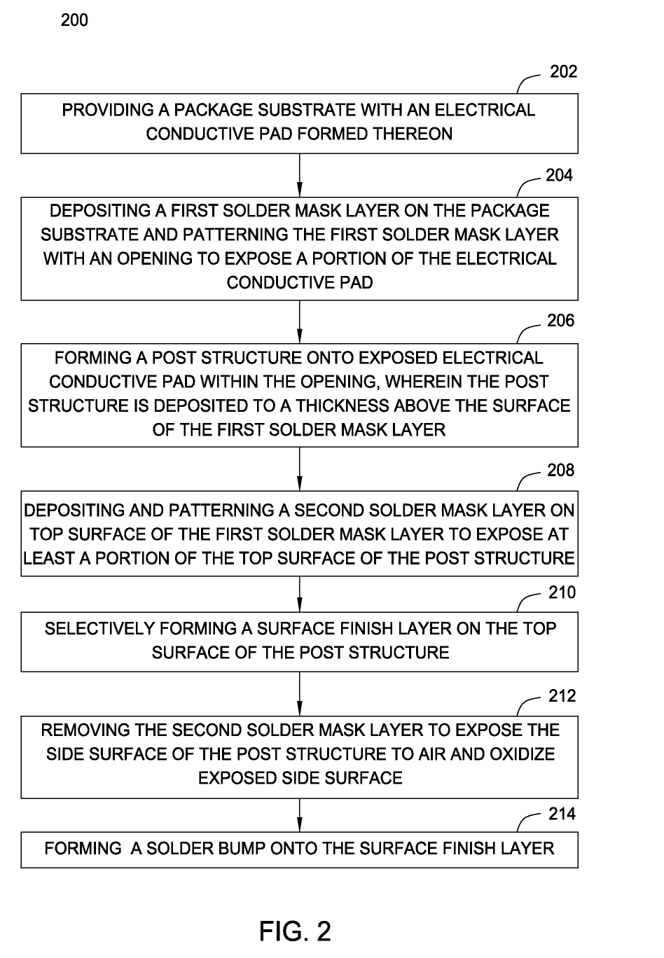

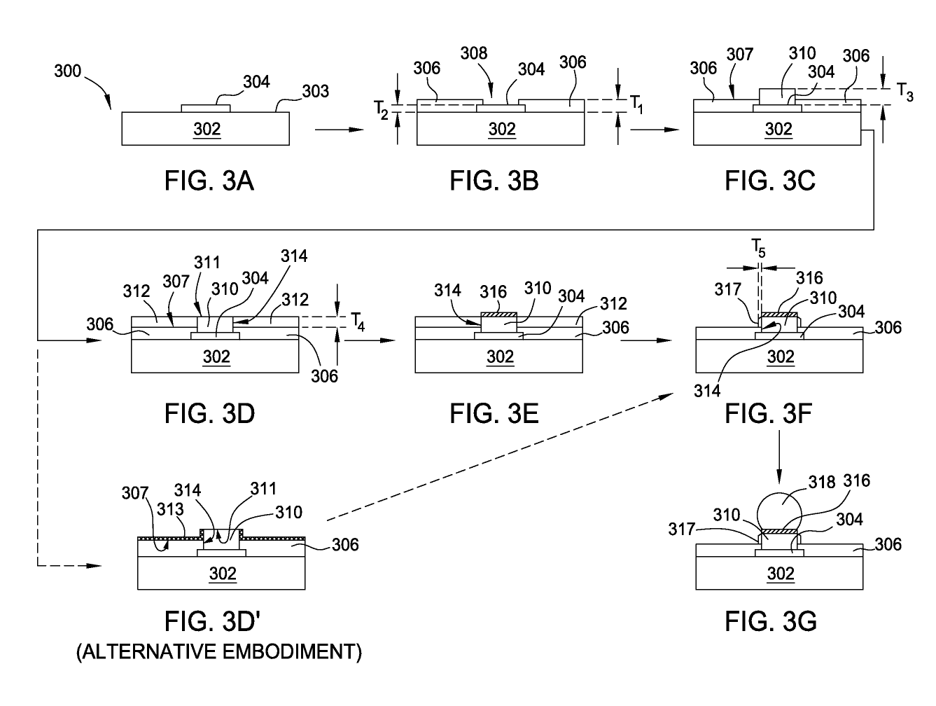

FIG. 2 illustrates an exemplary process sequence 200 used to form an integrated circuit system according to one embodiment of the invention. FIGS. 3A-3G illustrate schematic cross-sectional views of an integrated circuit (IC) system 300 at different stages of the process sequence shown in FIG. 2. It should be noted that the number and sequence of steps illustrated in FIG. 2 are not intended to be limiting since one or more steps may be added, deleted and/or reordered without deviating from the basic scope of the invention.

The process sequence 200 starts at step 202, which provides a package substrate 302 having a preformed electrically conductive pad 304 disposed thereon, as shown in FIG. 3A. For ease of understanding, only one electrically conductive pad is shown. Depending upon the application and the size of the package substrate, two or more electrically conductive pads may be formed on the package substrate 302. The electrically conductive pad 304 may be formed on a top surface 303 of the package substrate 302 by any suitable deposition process known in the art, such as an electroplating process or a physical vapor deposition (PVD) process. The electrically conductive pad 304 may be made of any electrically conductive material such as copper, aluminum, gold, silver, or alloys of two or more elements.

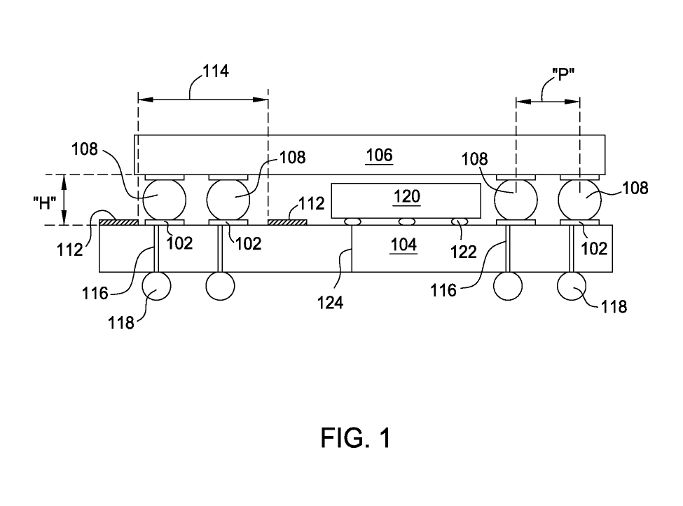

The package substrate 302 may be a laminate substrate comprised of a stack of insulative layers. While not shown, the package substrate 302 may have conductive lines (such as conductive lines 116, 124 shown in FIG. 1) embedded or formed therein. The conductive lines can be a plurality of horizontally oriented wires or vertically oriented vias running within the package substrate 302 to provide power, ground and/or input/output (I/O) signal interconnections between integrated circuit chips and a PCB. The package substrate 302 therefore provides the IC system 300 with structural rigidity and an electrical interface for routing input/output signals and power between a high-power chip (i.e., the high-power chip 120 of FIG. 1), a low-power chip (i.e., the low-power chip 106 of FIG. 1) and the PCB.

Suitable materials that may be used to make the package substrate may include, but are not limited to FR-2 and FR-4, which are traditional epoxy-based laminates, and the resin-based Bismaleimide-Triazine (BT) from Mitsubishi Gas and Chemical. FR-2 is a synthetic resin bonded paper having a thermal conductivity in the range of about 0.2 W/(K-m). FR-4 is a woven fiberglass cloth with an epoxy resin binder that has a thermal conductivity in the range of about 0.35 W/(K-m). BT/epoxy laminate packaging substrates also have a thermal conductivity in the range of about 0.35 W/(K-m). Other suitably rigid, electrically isolating, and thermally insulating materials that have a thermal conductivity of less than about 0.5 W/(K-m) may also be used.

In step 204, a first solder mask layer 306 is deposited on the package substrate 302 and patterned with an opening 308 to expose a portion of the electrically conductive pad 304 for subsequent post structure formation, as shown in FIG. 3B. The size of the opening 308 may vary depending upon the pitch between solder bumps to be formed on the electrically conductive pad 304. In one example, the opening 308 is between about 0.1 μm and about 500 μm in diameter, for example about 5 μm and about 100 μm. The first solder mask layer 306 provides electrical isolation of the package substrate 304 and may serve as a protective layer providing chemical and abrasion resistance to the package substrate 302. The first solder mask layer 306 may be made of a polymer with high fluidity, for example, an epoxy resin or a polyester resin.

Depending upon the application, the electrically conductive pad 304 may be a solder mask defined (SMD) pad whose periphery is covered by the solder mask layer 306 as shown, or a non-solder mask defined (NSMD) pad which is completely free from contacting the solder mask layer. Having the electrically conductive pad 304 contacted the first solder mask layer 306 may prevent potential pad lifting with the solder paste and the associated shrinkage issues, which may occur during solidification of the subsequent post structure formation. The first solder mask layer 306 may be deposited to a predetermined thickness. For example, the first solder mask layer 306 may be deposited to a thickness about half height of a subsequently-formed post structure (see FIG. 3C). In various examples, the first solder mask layer 306 may have a thickness “T₁” of about 25 μm to about 55 μm, for example about 40 μm. The electrically conductive pad 304 may have a thickness “T₂” of about 10 μm to about 30 μm, such as about 15 μm.

In step 206, a post structure 310 is formed onto the exposed electrically conductive pad 304 within the opening 308. The post structure 310 may be deposited to a thickness above the top surface 307 of the first solder mask layer 306, as shown in FIG. 3C. The post structure 310 may have a thickness “T₃”, which may vary depending upon the height of an integrated circuit chip (e.g., high-power chip) disposed between the package substrate 302 and an adjacent, parallel package substrate, and depending upon minimum bridging capability of the solder bumps to be formed on the post structure 310. In one embodiment, the thickness “T₃” may be between about 2 μm to about 200 μm, for example about 30 μm to about 70 μm. In one example, the integrated circuit chip is coupled to the top surface 307 of the first solder mask layer 306. The post structure 310 is provided to increase aspect ratio of an electrical connection between two adjacent package substrates while maintaining a required standoff height to accommodate the integrated circuit chip disposed between the two adjacent package substrates. Therefore, the post structure 310 helps compensate for finer solder bump pitch and the accordingly reduced size of solder bumps. The post structure 310 may have a cylindrical shape or any other shape that is suitable for holding the solder bump.

A “high-power chip,” as described herein, may be any semiconductor device operating at high voltages, such as a central processing unit (CPU), a graphics processing unit (GPU), an application processor or any other logic device that generates at least 10 W of heat or more during normal operation.

The post structure 310 may be made of an electrically conductive material with solder wettability. For example, the post structure 310 may be made of a copper material. The term “copper material” described herein may include pure elemental copper, copper-containing material, or copper alloy. The post structure 310 may be formed by any known deposition process such as electroplating, electroless plating, sputtering, printing, or chemical vapor deposition (CVD).

In step 208, a second solder mask layer 312 is deposited and patterned on the top surface 307 of the first solder mask layer 306 to expose at least a portion of the top surface 311 of the post structure 310, as shown in FIG. 3D. The second solder mask layer 312 may be deposited to a thickness “T₄” that is about the same height as the top surface 311 of the post structure 310. Therefore, the second solder mask layer 312 covers the exposed side surface 314 of the post structure 310, with the top surface 311 of the post structure 310 being exposed to air. In one example, the thickness “T₄” is between about 5 μm to about 80 μm, for example about 15 μm to about 45 μm. The second solder mask layer 312 may be formed using the same deposition technique as the first solder mask layer 306.

Alternatively, instead of depositing two separate solder mask layers (i.e., the first and second solder mask layers 306, 312), a single, thicker solder mask layer may be initially deposited on the package substrate 302. In such a case, the solder mask layer may be deposited to a thickness that is capable of covering the exposed side surface of the subsequently formed post structure.

In step 210, a surface finish layer 316 is selectively formed on the top surface 311 of the post structure 310, as shown in FIG. 3E. The surface finish layer 316 is provided to protect the top surface 311 of the post structure 310 from oxidation while enhancing solder wetability of the post structure. Since the side surface 314 of the post structure 310 is covered by the second solder mask layer 312, the surface finish layer 316 will only form on the exposed top surface 311 of the post structure 310. During step 210, the top surface 311 of the post structure 310 may be first cleaned using alkaline, acid or neutral cleaning solution, and then immersed in or sprayed with a solution containing an organic solderability preservative (OSP) material such as triazole, imidazole, benzimidazole or derivatives thereof to form the surface finish layer 316. Alternatively, the surface finish layer 316 may be formed of a nickel-gold, a nickel-silver, a nickel-platinum-gold, an immersion silver, or an immersion tin finish. Any other material that is suitable for providing protection against copper solderability degradation may also be used. Once the surface finish layer 316 has been formed, the package substrate 302 may be rinsed with deionized water.

In step 212, the second solder mask layer 312 is removed to expose the first solder mask layer 306 and the side surface 314 of the post structure 310, as shown in FIG. 3F. The second solder mask layer 312 may be removed using any known technique such as an ultraviolet (UV) laser or a plasma etching process. Upon removal of the second solder mask layer 312, a portion of the side surface 314 of the post structure 310 is exposed to air while the top surface of the post structure 310 is coated with the surface finish layer 316. The side surface 314 of the post structure 310, which is formed of copper material, has a tendency to be oxidized during the manufacturing process since the side surface 314 is not protected by the surface finish layer 316. Therefore, an oxidation layer 317 will be formed on the side surface 314 of the post structure 310. The thickness “T₅” of the oxidation layer 317 may vary depending upon the length of time the side surface 314 is exposed to the air. In one example, the oxidation layer 317 may have a thickness of about 0.5 μm to about 30 μm, for example about 5 μm. Most importantly, the oxidation layer 317 prevents the solder bump that is to be formed on the top surface of the post structure 310 from forming on the side surface 314.

It is contemplated that a portion of the first solder mask layer 306 may or may not be removed during the etching process. If desired, the entire first and second solder mask layers 306, 312 may be removed with a suitable etching process without damaging the electrically conductive pad 304 and other components such as the post structure 310 and the surface finish layer 316 formed thereon.

In an alternative embodiment as shown in FIG. 3D′, a second solder mask layer as discussed above with respect to step 208 may not be required to mask the exposed side surface 314 of the post structure 310. Instead, a mask layer is used to cover the side surface 314 of the post structure 310 to prevent the side surface 314 from coating with the subsequently formed surface finish layer. For example, after the post structure 310 has been formed onto the exposed electrically conductive pad 304 as discussed above in step 206, a mask layer 313 that is made of a photo-imageable composition may be applied in the form of a dry film onto the exposed top surface 307 of the first solder mask layer 306 and the exposed surfaces of the post structure 310 (i.e., top surface 311 and side surface 314).

After the mask layer has been formed, the package substrate 302 may be subjected to heat and/or radiation, such as UV radiation, to selectively remove the mask layer from the top surface 311 of the post structure 310, as shown in FIG. 3D′. Alternatively, the mask layer may be selectively hardened through an exposure process of exposing the dry film to light and only an unhardened portion is dissolved with a developer to pattern the dry film, thereby exposing the top surface 311 of the post structure 310. In either case, a surface finish layer is then selectively formed on the exposed top surface 311 of the post structure 310 via a mask, or in a manner as discussed above with respect to step 210. Thereafter, the mask layer 313 remaining on the exposed side surface 314 and the first solder mask layer 306 313 may be removed using heat and/or UV radiation. The exposed side surface 314 is then oxidized with time to form an oxidization layer 317, as discussed above with respect to step 212 and shown in FIG. 3F.

In step 214, upon the exposed side surface 314 has been oxidized, a solder bump 318 is formed on the surface finish layer 316 disposed on the top surface of the post structure 310, as shown in FIG. 3G. The surface finish layer 316 formed on the top surface of the post structure 310 creates a strong surface tension to the solder bump 318 and prevents the solder bump 318 from pulling over the edge of the post structure 310. In addition, since the side surface 314 has been oxidized and covered by the oxidation layer 317, the solder bump 318 will only wet and form on the top surface of the post structure.

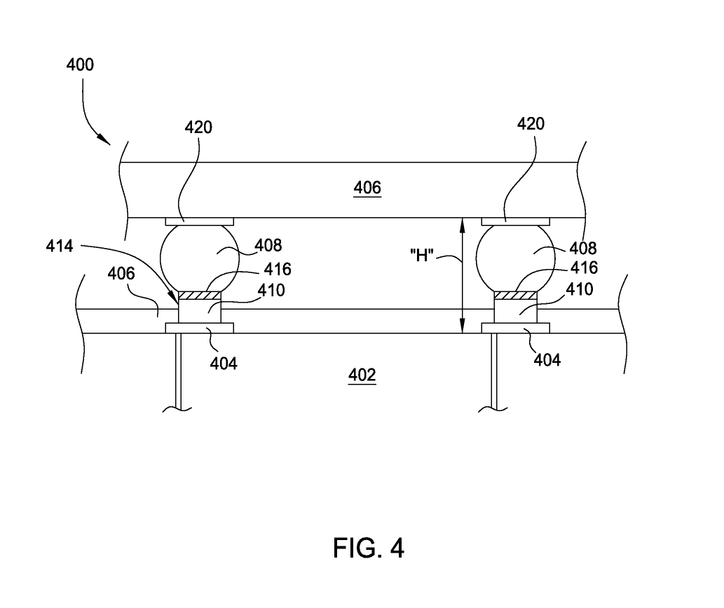

The solder bump 318 may be formed by depositing a pre-formed microsphere of a solder alloy on the surface finish layer 316 and heating to reflow the solder alloy. Upon cooling to solidify the solder bump 318, the package substrate 302 is soldered to a conductor pattern by registering the solder bump 318 with its respective conductor pad (e.g., conductor pads 420 formed on an adjacent package substrate 406, as shown in FIG. 4) and then reheating the solder bump 318. During flip chip assembly, the solder bump metallurgically adheres, and thus electrically interconnects, with its corresponding conductor pad formed on the adjacent package substrate to establish a solder joint connection between two adjacent package substrates.

The formed solder bump 318 typically has a round or substantially spherical shape due to surface tension of the molten solder alloy during reflow. The surface tension of the molten solder alloy also keeps the package substrate 302 at a distance during flip chip assembly. In cases where solder bumps are placed at a fine pitch of about 0.3 mm to about 0.5 mm, the size of the solder bump 318 may be between about 40 μm and about 300 μm in diameter. It is contemplated that the size of the solder bump 318 may vary depending upon the bump pitch and the surface area of the top surface of the post structure 310. In any cases, the height of the formed solder bump 318, when formed on the surface finish layer 316 of the post structure 310, should provide a sufficient bridging capability with the adjacent package substrate such that a standoff height between the package substrate 302 and the adjacent, parallel package substrate can be substantially maintained in order for an integrated circuit chip (e.g., a high-power chip) to fit properly in between the package substrate 302 and the adjacent, parallel package substrate.

FIG. 4 illustrates a partial, schematic cross-sectional view of an integrated circuit (IC) system 400 according to one embodiment of the invention. FIG. 4 may represent a stage following step 214, i.e., after the solder bump has been formed on the post structure to establish a solder joint connection between two adjacent package substrates. As can be seen, the IC system 400 generally includes a first package substrate 402 and a second package substrate 406 that is oriented parallel to the first package substrate 402. While not shown, the second package substrate 406 may contain an integrated circuit chip, such as a low-power chip. A “low-power chip,” as described herein, may be any semiconductor device operating at a voltage relatively lower than that of a high-power chip. For example, low-power chip may be a passive device located in IC system, a memory device or any other chip that generates on the order of about 1 W of heat, i.e., no more than about 5 W, during normal operation.

As discussed above in FIGS. 3A-3G, by having the top surface of the post structure 410 coated with a surface finish layer 416, the solder bump 408 connects only to the surface finish layer 416 that is deposited on the top surface of the post structure 410, rather than covering all the exposed surfaces (including side surface 414) of the post structure 410. As a result, the resulting solder joint structure is narrower and taller. Therefore, even if the solder bumps 408 are placed at a finer pitch and accordingly reduced size of solder bumps, a standoff height “H” between the package substrate 402 and the package substrate 406 can still be maintained at a desired height, with the same or less amount of solder volume, to accommodate the fixed-size integrated circuit chip (e.g., high power chip) that is typically disposed between the package substrate 402 and the adjacent package substrate 406.

The present invention is applicable to any packaging system in which a post structure is used to facilitate an electrical connection between two adjacent package substrates. The present invention is also applicable to any electrical device that needs a post structure and a solder joint to obtain a maximum standoff height and a minimum width of the solder joint.

In sum, embodiments of the present invention enable maintenance of a constant vertical standoff distance between a first and a second package substrates, even with decreasing solder bump pitch, by having the solder bump connected only to a top surface of a post structure that is formed on the first package substrate. The top surface of the post structure is coated with a surface finish layer to enhance solder wetability of the solder bump while preventing the top surface of the post structure from oxidation. The side surface of the post structure is oxidized to prevent the solder bump from wetting the side surface of the post structure. The resulting solder joint structure is taller since the solder bump does not cover the side surface of the post structure, thereby forming an electrical connection between the first and second package substrates that has a higher aspect ratio. The increased aspect ratio of this electrical connection maintains a standoff height that can accommodate an integrated circuit chip disposed between the first and second package substrates. The increased aspect ratio of such an electrical connection also compensates for reduced solder bump pitch and the accordingly reduced size of solder bumps. Therefore, for a particular width of solder bump, the solder joint standoff can be increased, as compared to the conventional approach where the solder bump covers all exposed surfaces of the post structure.

While the foregoing is directed to embodiments of the present invention, other and further embodiments of the invention may be devised without departing from the basic scope thereof. The scope of the different embodiments is determined by the claims that follow.

We claim:

1. A packaging system, comprising:
a first package substrate;
an electrically conductive pad formed on a surface of the first package substrate;
a supporting structure formed on the electrically conductive pad, wherein the supporting structure comprises a top surface and a side surface; and
a solder joint coupled to the top surface and not to the side surface of the supporting structure.

2. The packaging system of claim 1, wherein the side surface of the supporting structure comprises an oxidation layer.

3. The packaging system of claim 1, further comprising:
a solder mask layer formed on the surface of the first package substrate, wherein the solder mask layer defines an opening through which a portion of the electrically conductive pad is exposed to receive the supporting structure.

4. The packaging system of claim 3, wherein the solder mask layer is in physical contact with at least a portion of the electrically conductive pad.

5. The packaging system of claim 3, wherein the supporting structure extends above the solder mask layer.

6. The packaging system of claim 1, wherein the supporting structure comprises a copper-containing material.

7. The packaging system of claim 6, wherein the copper-containing material comprises pure elemental copper, copper-containing material, or copper alloy.

8. The packaging system of claim 1, further comprising a surface finish layer formed on the top surface.

9. The packaging system of claim 8, wherein the surface finish layer comprises an organic solderability preservative (OSP) material, a nickel-gold, a nickel-silver, a nickel-platinum-gold, an immersion silver, or an immersion tin finish.

10. The packaging system of claim 1, wherein the solder joint electrically connects the first package substrate to a first integrated circuit chip.

11. The packaging system of claim 10, wherein the first integrated circuit chip is included in a second package substrate.

12. The packaging system of claim 11, wherein the second package substrate is oriented substantially parallel to the surface of the first package substrate.

13. The packaging system of claim 12, further comprising:
a second integrated circuit chip disposed between the first package substrate and the second package substrate, wherein the second integrated circuit chip is coupled to the surface of the first package substrate.

14. The packaging system of claim 13, wherein the second integrated circuit chip generates at least 10 W of heat during normal operation and the first integrated circuit chip generates less than 5 W of heat during normal operation.

15. A method for manufacturing a packaging system, comprising:
providing a first package substrate having an electrically conductive pad formed thereon;
forming a supporting structure on the electrically conductive pad, wherein the supporting structure comprises a top surface and a side surface; and
coupling a solder joint to the top surface and not to the side surface of the supporting structure.

16. The method of claim 15, further comprising:
forming an oxidation layer on the side surface of the supporting structure.

17. The method of claim 15, wherein the supporting structure comprises a copper-containing material.

18. The method of claim 15, further comprising:
forming a surface finish layer on the top surface, wherein the surface finish layer comprises an organic solderability preservative (OSP) material, a nickel-gold, a nickel-silver, a nickel-platinum-gold, an immersion silver, or an immersion tin finish.

19. The method of claim 15, further comprising:
electrically connecting the first package substrate to a first integrated circuit chip through the solder joint, wherein the first integrated circuit chip is included in a second package substrate that is oriented substantially parallel to the surface of the first package substrate.

20. The method of claim 19, further comprising:
disposing a second integrated circuit chip between the first package substrate and the second package substrate, wherein the second integrated circuit chip is coupled to the surface of the first package substrate.

21. The method of claim 20, wherein the second integrated circuit chip generates at least 10 W of heat during normal operation and the first integrated circuit chip generates less than 5 W of heat during normal operation.
